(19) United States
(12) Patent Application Publication
(10) Pub. No.: US 2025/0275395 A1
(43) Pub. Date: Aug. 28, 2025

(54) Test Pattern and Display Device Including the Same

(71) Applicant: LG Display Co., Ltd., Seoul (KR)

(72) Inventors: Minseong Yun, Seoul (KR); Hyunki Kim, Hwaseong-si (KR); Ahrum Sohn, Seoul (KR)

(21) Appl. No.: 18/955,421

(22) Filed: Nov. 21, 2024

(30) Foreign Application Priority Data
Feb. 28, 2024 (KR) 10-2024-0028710

(51) Int. Cl. H10K 59/131; H10K 59/126

(52) U.S. Cl. CPC H10K 59/131; H10K 59/126

(57) ABSTRACT

Disclosed are a test pattern and a display device including the same. A first test wiring and a second test wiring are connected to a first electrode layer and a second electrode layer constituting the test pattern via a plurality of contact holes, respectively. Thus, current is applied to the first electrode layer and the second electrode layer via the first test wiring and the second test wiring, respectively. Thus, the current may be applied as uniformly as possible to an entire area of each of the first electrode layer and the second electrode layer.

### CROSS-REFERENCE TO RELATED APPLICATION

This application claims priority from Republic of Korea Patent Application No. 10-2024-0028710 filed on Feb. 28, 2024, which is hereby incorporated by reference in its entirety.

### BACKGROUND

### Field

The present disclosure relates to a test pattern that evaluates characteristics of an insulating film and a display device including the same.

### Description of Related Art

A display device is used in a variety of device such as televisions, monitors, smart phones, tablet personal computers (PCs), laptops, and wearable device.

The display device may display an image through a number of pixels included in a display area.

The display device may be manufactured in a manufacturing process that forms various types of elements such as thin-film transistors along with a stack structure of various types of insulating films and metal films.

In order to check whether a process result of the display device manufactured in this way properly functions, a thickness, resistance, and electrical characteristics of the process result may be measured.

For example, when the characteristics of the element such as the thin-film transistor formed in a display panel is directly measured, damage to the element may occur during the measurement process. Thus, it is difficult to monitor the characteristics of the actually formed thin-film transistor.

Therefore, in order to measure the characteristics of the actual element or insulating film to be measured, characteristics of a test element group (TEG) as a separate test pattern implemented to have the same structure as that of the actual element or insulating film may be measured in place of characteristics evaluation of the actual element or insulating film.

### SUMMARY

In the display panel, various types of insulating films may be formed not only in a display area where pixels are disposed, but also in a non-display area where a gate driver is disposed in a GIP (Gate In Panel) scheme.

During a manufacturing process of the display panel, a line defect may occur due to leakage of the insulating film.

In this case, a characteristics evaluation method that may monitor the defect in the insulating film during an inline process is needed.

In evaluating the characteristics of the insulating film, breakdown voltage (BV) measurement that sweeps the voltage may be used.

However, when the evaluation process includes applying voltage stress, foreign substances may be produced due to breakdown of the insulating film at a specific voltage, thereby making it difficult to evaluate absence or presence of the defect.

Accordingly, the evaluation process may include applying current stress so that the foreign substance is not produced during the evaluation process of the characteristics of the insulating film, and a more accurate evaluation of characteristics of the insulating film may be performed in the in-line process.

One of the evaluation schemes including applying the current stress may be time dependent dielectric breakdown (TDDB) evaluation under current stress application.

The TDDB evaluation under current stress application is a scheme of evaluating progressive insulation breakdown characteristics over time under application of a certain current stress to the insulation film.

Thus, a weak point in a thickness direction of the insulating film or the film characteristics of the insulating film may be evaluated.

In order to evaluate the intrinsic characteristics of the insulating film itself, a flat test pattern composed of a flat upper electrode and a lower electrode with an insulating film being disposed therebetween, and free of a separate pattern may be used.

However, when, in the flat test pattern, the current applied to the upper electrode or lower electrode is not uniform, the following problems may occur.

First, because the evaluation result on the insulation film characteristics varies, the consistency of the evaluation of the insulation film characteristics may be lowered.

Second, in order to connect to a test pad that applies the current to the test pattern thereto, the upper electrode extends beyond a side end of the lower electrode disposed under the upper electrode. In this case, a step in a vertical direction may occur due to a thickness of the lower electrode.

When the step occurs on the upper electrode, resistance may increase in the step area, causing the upper electrode to be torn.

The phenomenon that the upper electrode is torn may occur more intensively in a bottleneck area where an electrode width is smaller.

When the phenomenon that the upper electrode is torn in this way progresses in a faster manner than the breakdown of the insulating film itself progresses, the breakdown characteristics of the insulating film may not be measured.

The defect occurring in the insulating film may be affected not only by the defect caused by the film quality of the insulating film itself, but also by various factors that occur during a process.

For example, process influence due to external extrinsic factors, such as the step coverage that may occur in a process of forming a stack structure or a protrusion that may occur in a specific layer may be problematic.

However, in measuring the breakdown characteristics of the insulating film, it may be difficult to accurately determine whether the breakdown characteristics are due to the defect characteristics inherent in the insulating film itself or due to the process influence.

Accordingly, through various experiments, the inventors of the present disclosure have invented a test pattern which improves uniformity of the current applied to the test pattern and allows the insulating film characteristics due to the intrinsic characteristics of the insulating film and the insulating film characteristics due to the extrinsic characteristics thereto to be distinguished as accurately as possible, and have invented a display device including the test pattern.

In one embodiment, a test pattern comprises: a first electrode layer; a first insulating layer on the first electrode layer; a second electrode layer on the first insulating layer, the second electrode layer non-overlapping with an edge of the first electrode layer; a second insulating layer on the second electrode layer; a first test wiring on the second insulating layer, the first test wiring connected to the first electrode layer via a plurality of first contact holes that extend through the first insulating layer and the second insulating layer; and a second test wiring on the second insulating layer, the second test wiring connected to the second electrode layer via a plurality of second contact holes that extend through the second insulating layer.

In one embodiment, a test pattern comprises: a first electrode layer including a grid pattern of a plurality of openings in the first electrode layer; a first insulating layer on the first electrode layer; and a second electrode layer on the first insulating layer, the second electrode layer including a plurality of extensions that overlap the grid pattern of the plurality of openings.

In one embodiment, a display device comprises: a substrate including a display area and a non-display area; and at least one test pattern on the non-display area of the substrate, the at least one test pattern including: a first electrode layer; a first insulating layer on the first electrode layer; a second electrode layer on the first insulating layer, the second electrode layer non-overlapping with an edge of the first electrode layer; a second insulating layer on the second electrode layer; a first test wiring on the second insulating layer, the first test wiring connected to the first electrode layer via a plurality of first contact holes that extend through the first insulating layer and the second insulating layer; and a second test wiring on the second insulating layer, the second test wiring connected to the second electrode layer via a plurality of second contact holes that extend through the second insulating layer.

In one embodiment, a display device comprises: a substrate including a display area and a non-display area; and at least one test pattern on the non-display area of the substrate, the at least one test pattern including: a first electrode layer including a grid pattern of a plurality of openings in the first electrode layer; a first insulating layer on the first electrode layer; and a second electrode layer on the first insulating layer, the second electrode layer including a plurality of extensions that overlap the grid pattern of the plurality of openings.

In one embodiment, a test pattern comprises: a first electrode layer; a first insulating layer on the first electrode layer; a second electrode layer on the first insulating layer, the second electrode layer non-overlapping with an edge of the first electrode layer; a second insulating layer on the second electrode layer; a first test wiring on the second insulating layer, the first test wiring connected to the first electrode layer; and a second test wiring on the second insulating layer, the second test wiring connected to the second electrode layer, wherein an end of the first test wiring and an end of the second test wiring are on a same plane.

A purpose according to an embodiment of the present disclosure is to provide a test pattern that may apply current which is as uniform as possible to an entire area of an electrode layer constituting the test pattern and a display device including the test pattern.

In addition, a purpose according to an embodiment of the present disclosure is to provide a test pattern that may prevent damage to the first and second electrode layers constituting the test pattern from occurring before the breakdown of the insulating film, and a display device that includes the test pattern.

In addition, a purpose according to an embodiment of the present disclosure is to provide a test pattern that may more precisely define an overlapping area size of the first electrode layer and the second electrode layer that may define an evaluation area size of the insulating film, and a display including the test pattern.

In addition, a purpose according to an embodiment of the present disclosure is to provide a test pattern that may evaluate defect characteristics inherent in the film itself of the insulating film while not being affected as much as possible by the process influence due to the process, and a display including the test pattern.

In addition, a purpose according to an embodiment of the present disclosure is to provide a test pattern that may more accurately and precisely evaluate the characteristics the insulating film under the process influence due to the process as the extrinsic factor, and a display including the test pattern.

In addition, a purpose according to an embodiment of the present disclosure is to provide a test pattern that may evaluate the characteristics of various types of insulating films, such as a buffer layer or a gate insulating layer, and a display device including the same.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In the test pattern according to an embodiment of the present disclosure, the first test wiring and the second test wiring may be connected to the first electrode layer and the second electrode layer constituting the test pattern via the plurality of contact holes, respectively. Thus, the current may be applied to the first electrode layer and the second electrode layer via the first test wiring and the second test wiring, respectively. Thus, the current may be applied as uniformly as possible to an entire area of each of the first electrode layer and the second electrode layer.

In addition, in the test pattern according to an embodiment of the present disclosure, the separate first test wiring may be connected to the first electrode layer constituting the first test pattern via the plurality of first contact holes. Thus, the current may be applied to the first electrode layer via the first test wiring. The first electrode layer is not required to extend directly to the first test pad so as to be connected to the first test pad.

This may prevent the breakdown of the first electrode layer from occurring before the breakdown of the insulating film due to an increase in the resistance near the bottleneck area of the first electrode layer which has a narrow width and is not sufficiently conductivized when the first electrode layer of the first test pattern acts as the active layer.

In addition, in the test pattern according to an embodiment of the present disclosure, the separate second test wiring may be connected to the second electrode layer constituting the test pattern via the plurality of second contact holes. Thus, the current may be applied to the second electrode layer via the second test wiring. The second electrode layer is not required to extend directly to the second test pad so as to be connected to the second test pad.

Accordingly, a step in the vertical direction of the second electrode layer that may occur in an outer boundary area of the first electrode layer may not occur, thereby preventing breakdown of the second electrode layer from occurring before the breakdown of the insulating film due to an increase in resistance near the bottleneck area having the narrow width of the second electrode layer.

In addition, in the test pattern according to an embodiment of the present disclosure, the first test wiring and the second test wiring may be connected to the first electrode layer and the second electrode layer constituting the test pattern via the plurality of contact holes, respectively. Thus, the current may be applied to the first electrode layer and the second electrode layer via the first test wiring and the second test wiring, respectively. Thus, the defect characteristics inherent in the insulating film itself may be evaluated without being influenced as much as possible by the process influences due to the process. Thus, the consistency of the characteristics evaluation of the insulating film may be improved.

Due to the large number of step areas formed in this way, the number of evaluation samplings that may be used to evaluate the step coverage of the insulating film increases, such that the characteristics such as the step coverage of the insulating film affected by the process influence due to the process as the extrinsic factor may be evaluated more accurately and precisely.

In addition, in the test pattern according to an embodiment of the present disclosure, the first electrode layer and the second electrode layer constituting the test pattern may include the grid pattern and the extensions, respectively, which are positioned to vertically overlap each other. Accordingly, unlike a test pattern that breaks down all at once, the breakdown may occur in the test pattern several times step-by-step. Thus, the characteristics of the insulating film under the process influence may be evaluated more accurately and precisely.

Further, according to an embodiment of the present disclosure, the first electrode layer or the second electrode layer among the first electrode layer and the second electrode layer constituting the test pattern may act as an active layer to evaluate the characteristics of the insulating film. Thus, the film characteristics of various types of insulating films such as the buffer layer or the gate insulating layer located on top of or under the active layer, and the characteristics thereof under the process influence may be more accurately and precisely evaluated. Thus, a display device with a long lifespan and lowered power consumption may be realized.

Further, according to an embodiment of the present disclosure, the characteristics of the insulating film due to the intrinsic factor of the insulating film and the characteristics of the insulating film due to the extrinsic factor to the insulating film may be measured in a clearly distinguished manner from each other using the test pattern.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a schematic plan view of a display device according to an embodiment of the present disclosure.

FIG. 2 is a cross-sectional view of one sub-pixel according to an embodiment of the present disclosure.

FIG. 3 and FIG. 4 are a plan view and a cross-sectional view of a test pattern according to an embodiment of the present disclosure, respectively.

FIG. 5 and FIG. 6 are a plan view and a cross-sectional view of a test pattern according to another embodiment of the present disclosure, respectively.

FIGS. 7 to 11 are process plan views of the test pattern as shown in FIG. 5 according to an embodiment.

FIGS. 12 to 16 are process cross-sectional views of the test pattern as shown in FIG. 6 according to an embodiment.

FIG. 17 and FIG. 18 are plan views of a test pattern according to still another embodiment of the present disclosure.

FIG. 19 and FIG. 20 are respectively a plan view and a cross-sectional view of a test pattern according to still yet another embodiment of the present disclosure.

FIG. 21 is a plan view of a test pattern according to still yet another embodiment of the present disclosure.

FIG. 22 is an enlarged view of an area where a grid pattern and an extension of the test pattern overlap each other according to an embodiment as shown in FIG. 21.

FIGS. 23 to 25 are cross-sectional views of FIG. 22, according to different embodiments of the present disclosure.

FIG. 26 is a plan view of a test pattern according to still yet another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be embodied in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for illustrating embodiments of the present disclosure are illustrative, and the present disclosure is not limited thereto. For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

In interpreting a numerical value, the value is interpreted as including an error range unless there is no separate explicit description thereof.

Further, as used herein, when a layer, film, region, plate area, or the like is be disposed “on” or “on a top” of another layer, film, region, plate area, or the like, the former may directly contact the latter or still another layer, film, region, plate area, or the like may be disposed between the former and the latter. As used herein, when a layer, film, region, plate area, or the like is directly disposed “on” or “on a top” of another layer, film, region, plate area, or the like, the former directly contacts the latter and still another layer, film, region, plate area, or the like is not disposed between the former and the latter. Further, as used herein, when a layer, film, region, plate area, or the like is disposed “below” or “under” another layer, film, region, plate area, or the like, the former may directly contact the latter or still another layer, film, region, plate area, or the like may be disposed between the former and the latter. As used herein, when a layer, film, region, plate area, or the like is directly disposed “below” or “under” another layer, film, region, plate area, or the like, the former directly contacts the latter and still another layer, film, region, plate area, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be embodied independently of each other and may be embodied together in an association relationship.

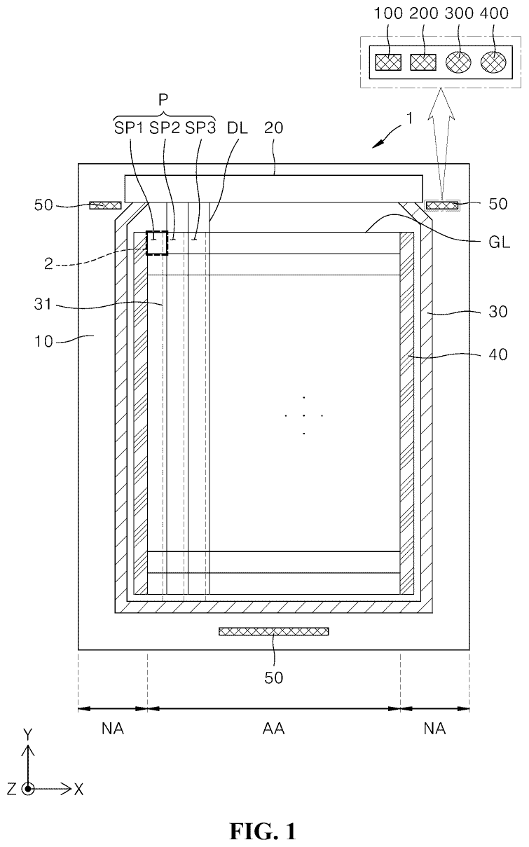

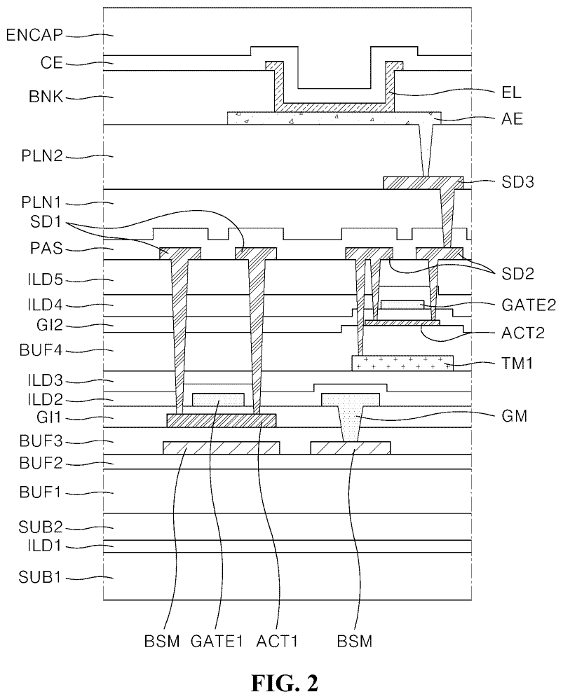

Hereinafter, with reference to FIG. 1 to FIG. 2, a display device according to an embodiment of the present disclosure will be described in detail.

FIG. 1 is a schematic plan view of a display device according to an embodiment of the present disclosure.

An example in which a display device 1 is embodied as an organic electroluminescent display device (organic light-emitting diode display device) is described below. However, embodiments of the present disclosure are not limited thereto.

The display device 1 may include a substrate 10 including a display area AA and a non-display area NA surrounding the display area AA.

In on the display area AA of the substrate 10, a plurality of data lines DL extending in a first direction and a plurality of gate lines GL extending in a second direction intersecting the first direction may be arranged.

Each of sub-pixels SP1, SP2, and SP3 may be disposed in each of intersections of the data lines DL and the gate lines GL.

The sub-pixels SP1, SP2, and SP3 may emit light of the same color, such as white (W) light, or red (R), green (G), or blue (B) light, or may emit light beams of different colors.

A combination of the plurality of sub-pixels SP1, SP2, and SP3 as described above may constitute one pixel P.

The plurality of sub-pixels SP1, SP2, and SP3 may be arranged in a plurality of rows and columns in a matrix format.

As used herein, the first direction may be a column direction and may be defined as a Y-axis direction, and the second direction may be a row direction and may be defined as a X-axis direction.

A number of lines and pads that supply various signals and powers to the pixel may be disposed on the non-display area NA of the substrate 10.

A data driver (D-IC) 20 may be disposed in one side aera of the non-display area NA.

The data driver 20 may apply a data signal to the data line DL, and may apply a driving voltage such as a high potential voltage VDD or a low potential voltage VSS to the pixel P.

A power line 30 may extend along an edge of the display area AA and in the other side areas of the non-display area NA other than one side area in which the data driver 20 is disposed.

For example, a gate driver 40 that applies a gate signal to the gate line GL may be disposed in the non-display area NA and located on each of both opposing sides of the display area AA. The power line 30 capable of applying a voltage to an anode electrode or a cathode electrode in the pixel P may extend along an outer edge of the gate driver 40 and in the non-display area NA.

The gate driver 40 formed on the substrate 10 in a GIP (Gate-In-Panel) scheme may be named a GIP driver.

The power line 30 may include a low-potential voltage line capable of applying a low-potential voltage VSS to the cathode electrode of the pixel P. However, embodiments of the present disclosure are not limited thereto. The power line 30 may further include a high-potential voltage line capable of applying a high-potential voltage VDD to a thin-film transistor of the pixel P.

A plurality of power connection lines 31 may be disposed in the display area AA and may be electrically connected to and disposed between the power line 30 to the plurality of sub-pixels SP1, SP2, and SP3 and may apply the low potential voltage to the plurality of sub-pixels SP1, SP2, and SP3.

For example, the plurality of power connection lines 31 may extend in the first direction in which the plurality of data lines DL extend by an equal length.

In one example, one or more test patterns 50 may be disposed on the non-display area NA of the substrate 10.

In one example, the test pattern 50 may be disposed near an area where the data driver 20 is disposed. However, embodiments of the present disclosure are not limited thereto and the test pattern 50 may be disposed in an opposite area to the area where the data driver 20 is disposed.

Further, the test pattern 50 may be additionally designed and disposed in an area in which a free space is formed in the non-display area NA. The test pattern 50 is not disposed in the display area AA.

The test pattern 50 may include a plurality of test patterns 100, 200, 300, and 400.

In one example, the test pattern 50 may include the plurality of test patterns that have various pattern shapes and may be used to evaluate various types of insulating films. The plurality of test patterns may include the first test pattern 100, the second test pattern 200, the third test pattern 300, and the fourth test pattern 400, etc.

The number of test patterns included in one test pattern unit 50 is not particularly limited.

Referring to FIG. 2, the sub-pixel within the display area AA according to an embodiment of the present disclosure is described in detail.

The substrate 10 may include a first substrate SUB1, a first interlayer insulating layer ILD1, and a second substrate SUB2 sequentially stacked.

In one example, each of the first substrate SUB1 and the second substrate SUB2 may be embodied as a polyimide (PI) substrate.

The first interlayer insulating layer ILD1 is located between the first substrate SUB1 and the second substrate SUB2 to prevent moisture penetration.

The first interlayer insulating layer ILD1 may be embodied as an inorganic insulating film including silicon oxide (SiOx) or silicon nitride (SiNx). However, embodiments of the present disclosure are not limited thereto.

Additionally, the substrate 10 is not limited to the above substate, and may be embodied as a glass substrate.

One or more buffer layers BUF1 and BUF2 may be disposed on the substrate 10.

For example, the first buffer layer BUF1 and the second buffer layer BUF2 may be sequentially stacked on the substrate 10 to constitute a stack of a plurality of buffer layers.

In one example, the first buffer layer BUF1 and the second buffer layer BUF2 may be embodied as an inorganic insulating film including silicon oxide (SiOx) or silicon nitride (SiNx). However, embodiments of the present disclosure are not limited thereto.

A light-blocking layer BSM may be disposed on the first buffer layer BUF1 and the second buffer layer BUF2.

The light-blocking layer BSM may be positioned to overlap, in the vertical direction, with an active layer of a thin-film transistor, which will be described later, and may prevent light from being irradiated to the active layer.

In one example, the light-blocking layer BSM may include one or more metals of molybdenum (Mo), titanium (Ti), and copper (Cu), or an alloy thereof, or may be formed in a multi-layer structure in which layers made of these metals are stacked. However, embodiments of the present disclosure are not limited thereto.

A third buffer layer BUF3 may be formed on the light-blocking layer BSM.

In one example, the third buffer layer BUF3 may be embodied as an inorganic insulating film including silicon oxide (SiOx) or silicon nitride (SiNx). However, embodiments of the present disclosure are not limited thereto.

A first active layer ACT1 may be disposed on the third buffer layer BUF3.

In one example, the first active layer ACT1 may include low-temperature polycrystalline silicon (LTPS). However, embodiments of the present disclosure are not limited thereto. The first active layer ACT1 may include amorphous silicon (a-Si) or oxide semiconductor material.

In one example, the oxide semiconductor material may include, for example, IGZO (Indium-gallium-zinc-oxide), IZO (Indium-zinc-oxide), IGZTO (Indium-gallium-zinc-tin-oxide), IGTO (Indium-gallium-tin-oxide), and IGO (Indium-gallium-oxide).

A first gate insulating layer GI1 may be disposed on the first active layer ACT1.

In one example, the first gate insulating layer GI1 may be embodied as an inorganic insulating film including silicon oxide (SiOx) or silicon nitride (SiNx). However, embodiments of the present disclosure are not limited thereto.

A first gate electrode GATE1 may be disposed on the first gate insulating layer GI1.

In one example, the first gate electrode GATE1 may be made of one metal selected from the group consisting of molybdenum (Mo), aluminum (Al), chromium (Cr), gold (Au), titanium (Ti), nickel (Ni), and copper (Cu), or an alloy thereof, and may be embodied as a single layer or a stack of multiple layers.

A gate metal layer GM formed in the same layer as that of the first gate electrode GATE1 may be electrically connected to the light-blocking layer BSM via a contact hole extending through the first gate insulating layer GI1 and the third buffer layer BUF3.

In this case, the gate metal layer GM may be a layer extending from the first gate electrode GATE1.

A second interlayer insulating layer ILD2 and a third interlayer insulating layer ILD3 may be disposed on the first gate electrode GATE1 and the gate metal layer GM.

In one example, each of the second interlayer insulating layer ILD2 and the third interlayer insulating layer ILD3 may be embodied as an inorganic insulating film including silicon oxide (SiOx) or silicon nitride (SiNx). However, embodiments of the present disclosure are not limited thereto.

A first metal pattern layer TM1 may be disposed on the third interlayer insulating layer ILD3.

The first metal pattern layer TM1 may function as a light-blocking layer.

In this case, the first metal pattern layer TM1 may be positioned to be spaced apart from the first active layer ACT1 as described above and so as not to overlap, in the vertical direction, therewith, and may be positioned to overlap, in the vertical direction, with a second active layer ACT2 to be described later.

In one example, the first metal pattern layer TM1 may include one or more metals of molybdenum (Mo), titanium (Ti), and copper (Cu), or an alloy thereof, or may be formed in a multi-layer structure in which layers made of these metals are stacked. However, embodiments of the present disclosure are not limited thereto.

A fourth buffer layer BUF4 may be disposed on the first metal pattern layer TM1.

In one example, the fourth buffer layer BUF4 may be embodied as an inorganic insulating film including silicon oxide (SiOx) or silicon nitride (SiNx). However, embodiments of the present disclosure are not limited thereto.

The second active layer ACT2 may be disposed on the fourth buffer layer BUF4 so as to overlap the first metal pattern layer TM1 in the vertical direction.

In one example, the second active layer ACT2 may include an oxide semiconductor material. However, embodiments of the present disclosure are not limited thereto. The second active layer ACT2 may include low-temperature polycrystalline silicon (LTPS) or amorphous silicon (a-Si).

In one example, the oxide semiconductor material may include, for example, IGZO (Indium-gallium-zinc-oxide), IZO (Indium-zinc-oxide), IGZTO (Indium-gallium-zinc-tin-oxide), IGTO (Indium-gallium-tin-oxide), and IGO (Indium-gallium-oxide).

A second gate insulating layer GI2 may be disposed on the second active layer ACT2.

In one example, the second gate insulating layer GI2 may be embodied as an inorganic insulating film including silicon oxide (SiOx) or silicon nitride (SiNx). However, embodiments of the present disclosure are not limited thereto.

A second gate electrode GATE2 may be disposed on the second gate insulating layer GI2.

In one example, the second gate electrode GATE2 may be made of one metal selected from the group consisting of molybdenum (Mo), aluminum (Al), chromium (Cr), gold (Au), titanium (Ti), nickel (Ni), and copper (Cu), or an alloy thereof, and may be embodied as a single layer or a stack of multiple layers.

A fourth interlayer insulating layer ILD4 and a fifth interlayer insulating layer ILD5 may be disposed on the second gate electrode GATE2.

In one example, each of the fourth interlayer insulating layer ILD4 and the fifth interlayer insulating layer ILD5 may be embodied as an inorganic insulating film including silicon oxide (SiOx) or silicon nitride (SiNx). However, embodiments of the present disclosure are not limited thereto.

A pair of first source/drain electrodes SD1 and a pair of second source/drain electrodes SD2 may be disposed on the fifth interlayer insulating layer ILD5.

The pair of first source/drain electrodes SD1 may be electrically connected to one side and the other side of the first active layer ACT1, respectively, via contact holes extending through the insulating layers disposed thereunder.

In one example, one of the pair of first source-drain electrodes SD1 may be a first source electrode in contact with a source area of the first active layer ACT1, and the other thereof may be a first drain electrode in contact with a drain area of the first active layer ACT1.

Alternatively, positions of the first source electrode and the first drain electrode may be exchanged with other.

Additionally, the pair of second source-drain electrodes SD2 may be electrically connected to one side and the other side of the second active layer ACT2 via contact holes extending through the insulating layers disposed thereunder, respectively.

In one example, one of the pair of second source-drain electrodes SD2 may be a second source electrode in contact with a source area of the second active layer ACT2, and the other thereof may be a second drain electrode in contact with a drain area of the second active layer ACT2.

Alternatively, the positions of the second source electrode and the second drain electrode may be exchanged with each other.

One of the second source/drain electrodes SD2 may be electrically connected to the first metal pattern layer TM1.

In one example, each of the first source-drain electrode SD1 and the second source-drain electrode SD2 may be made of one metal selected from the group consisting of molybdenum (Mo), aluminum (Al), chromium (Cr), gold (Au), titanium (Ti), nickel (Ni), and copper (Cu), or an alloy thereof, and may be embodied as a single layer or a stack of multiple layers.

A passivation layer PAS may be disposed on the first source-drain electrode SD1 and the second source-drain electrode SD2.

In one example, the passivation layer PAS may be embodied as an inorganic insulating film including silicon oxide (SiOx) or silicon nitride (SiNx). However, embodiments of the present disclosure are not limited thereto.

A first planarization layer PLN1 may be disposed on the passivation layer PAS.

The second planarization layer PLN1 may include an organic insulating material.

A third source/drain electrode SD3 may be disposed on the first planarization layer PLN1.

The third source/drain electrode SD3 may function as a connection electrode connecting the second source/drain electrode SD2 and an anode electrode AND to each other.

The third source/drain electrode SD3 may be connected to one of the pair of second source/drain electrodes SD2 via a contact hole extending through the first planarization layer PLN1.

A second planarization layer PLN2 may be disposed on the third source/drain electrode SD3.

The second planarization layer PLN2 may include an organic insulating material.

The anode electrode AE may be disposed on the second planarization layer PLN2.

The anode electrode AND may be connected to the third source-drain electrode SD3 via contact hole extending through the second planarization layer PLN2.

A bank BNK may be disposed on the anode electrode AND.

The bank BNK may be formed to cover an edge of the anode electrode AE.

The bank BNK serves to distinguish the sub-pixels SP1, SP2, and SP3 from each other and has a function of preventing light beams of different colors respectively output between adjacent ones of the sub-pixels SP1, SP3, and SP3 from being mixed each other.

The bank BNK may include an organic insulating materials such as acryl resin, epoxy resin, phenolic resin, polyamide resin, or polyimide resin. However, embodiments of the present disclosure are not limited thereto.

A light-emitting layer EL may be disposed on the anode electrode AE.

The light-emitting layers EL in the sub-pixels SP1, SP2, and SP3 may include organic materials that emit light beams of different colors, respectively.

For example, the light-emitting layer EL may emit light of one color among red, green, blue, and white.

In addition, the light-emitting layer EL may be made of an organic material that emits white light. In this regard, color filters of different colors may be disposed on the light-emitting layer EL so as to emit light beams of red, green, and blue, respectively.

The light-emitting layer EL may be embodied as an organic light-emitting layer composed of a stack structure including a hole transport layer HTL, a light-emitting layer EML, and an electron transport layer ETL, a hole blocking layer HBL, a hole injection layer HIL, an electron blocking layer EBL, and an electron injection layer EIL.

The light-emitting layer EL may be formed to cover the anode electrode AE and a side surface and a portion of an upper surface of the bank BNK.

Additionally, the light-emitting layer EL may be formed over the entire display area AA so as to cover the anode electrode AE and an exposed surface of the bank BNK.

A cathode electrode CE may be disposed on the light-emitting layer EL.

The cathode electrode CE may be formed to cover the light-emitting layer EL.

The cathode electrode CE may be formed to extend to cover the plurality of pixels P.

A stack of the anode electrode AE, the light-emitting layer EL, and the cathode electrode CE formed in this way and overlapping each other may function as an organic light-emitting element (OLED) as a light-emitting element.

FIG. 2 shows an example in which the anode electrode AE is a lower electrode and the cathode electrode CE is an upper electrode. However, embodiments of the present disclosure ire not limited thereto, and the cathode electrode CE may act as the lower electrode and the anode electrode AE may act as the upper electrode.

An encapsulation layer ENCAP may be disposed on the cathode electrode CE.

The encapsulation layer ENCAP may have a single-layer structure or a multi-layer structure.

For example, the encapsulation layer ENCAP may have a structure in which an inorganic film, an organic film, and an inorganic film are sequentially stacked.

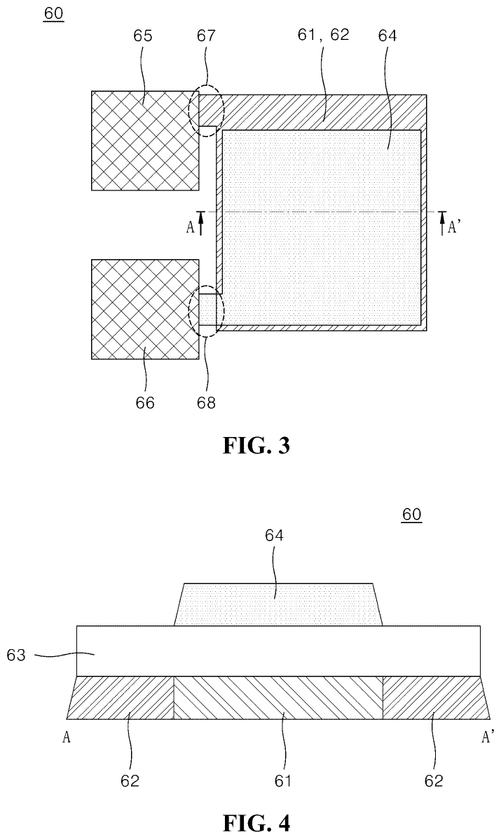

Hereinafter, with reference to FIG. 3 and FIG. 4, a test pattern 60 according to an embodiment of the present disclosure will be described.

The test pattern 60 may include a first electrode layer 61 and a second electrode layer 64 vertically arranged to face each other. That is, the second electrode layer 64 is on the first electrode layer 61 such that the second electrode layer 64 overlaps the first electrode layer 61.

An insulating layer 63 may be disposed between the first electrode layer 61 and the second electrode layer 64.

The first electrode layer 61 may be an active layer, the second electrode layer 64 may be a metal layer, and the insulating layer 63 may be an oxide layer.

Accordingly, the test pattern 60 may be a flat test pattern with a MOS (Metal-Oxide-Semiconductor) structure.

The first electrode layer 61 disposed under the second electrode layer 64 may be formed to have a larger area than that of the second electrode layer 64. That is, an area of the first electrode layer 61 is greater than an area of the second electrode layer 64.

Accordingly, the first electrode layer 61 may be formed to protrude further outwardly beyond the second electrode layer 64. That is, edge areas (e.g., ends) of the first electrode layer 61 extend edge areas of the second electrode layer 64.

An edge area of the first electrode layer 61 that protrudes outwardly beyond the second electrode layer 64 may be a conductivized area 62 that is conductive.

For example, the edge area of the first electrode layer 61 as the active layer corresponding to the conductivized area 62 may be doped with impurity ions such as phosphorus (P) or boron (B). Thus, the conductivized area 62 may be formed.

The first electrode layer 61 may extend in one side direction so that one side thereof is electrically connected to a first test pad 65. The second electrode layer 64 may extend in one side direction such that one side thereof is electrically connected to a second test pad 66.

The test pattern 60 may apply current to the second test pad part 66. The first test pad part 65 may be connected to a ground, so that the current flows through the first test pad 65.

As the current is applied via the second test pad 66, current stress may be applied via the second electrode layer 64 as the metal layer.

In order for the first electrode layer 61 to be electrically connected to the first test pad 65, one side of the first electrode layer 61 may include a first area 67 that extends from the first electrode layer 61 toward the first test pad 65. The first area 67 may have a width in a plan view that is less than a total width of the first electrode layer 61.

The first area 67 may be a first narrow bottle neck area.

Further, the first area 67 may belong to the conductivized area 62.

Additionally, in order for the second electrode layer 64 to be electrically connected to the second test pad 66, one side of the second electrode layer 64 may include a second area 68 that extends from the second electrode layer 61 toward the second test pad 66. The second area 68 may have a width in the plan view that is less than a total width of the second electrode layer 64.

The second area 68 may be a second narrow bottleneck area.

When the first electrode layer 61 extends so as to include the first area 67 such that the first electrode layer 61 is directly connected to the first test pad 65, the following problems may occur.

When the first electrode layer 61 is not uniformly conductivized, current flowing in different areas of first electrode layer 61 may not be uniform.

In this case, as the resistance increases significantly in the first area 67, the breakdown may occur in the first area 67 of the first electrode layer 61 before breakdown of the insulating layer 63.

Additionally, when the second electrode layer 64 extends to include the second area 68 so that the second electrode layer 64 is directly connected to the second test pad 66, the following problems may occur.

Because the second area 68 of the second electrode layer 64 extends beyond a side end of the first electrode layer 61, a step in a vertical direction may occur due to a thickness of the first electrode layer 61.

In this way, when the step occurs in the second area 68 of the second electrode layer 64, the resistance increases in the second area 68, which may cause the second electrode layer 64 to be torn.

In this case, as the resistance increases significantly in the second area 68, the breakdown of the second area 68 of the second electrode layer 64 may occur first before breakdown of the insulating layer 63.

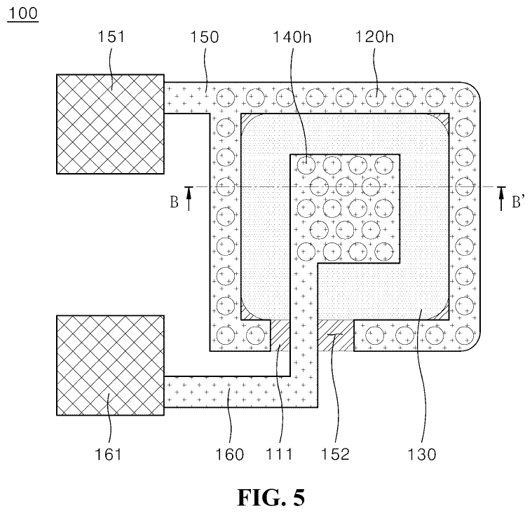

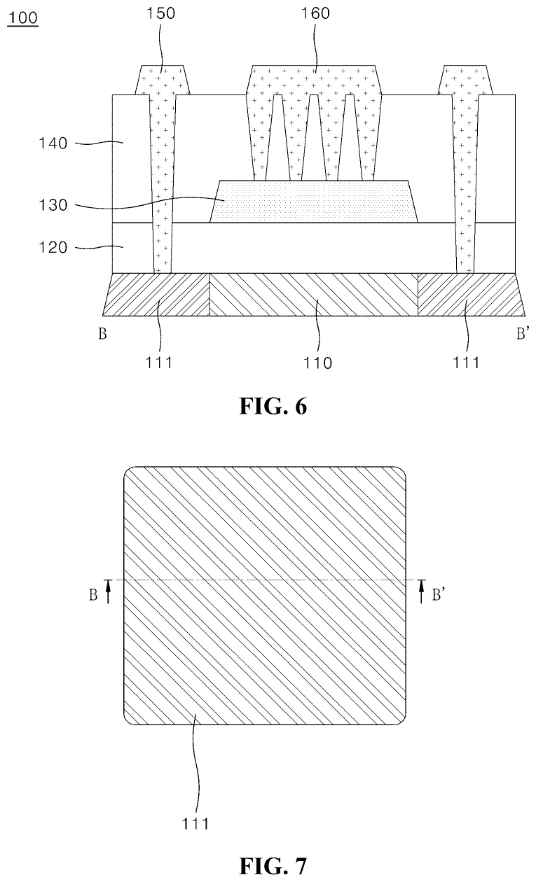

In order to solve these problems, a first test pattern 100 according to another embodiment of the present disclosure will be described below with reference to FIG. 5 and FIG. 6. For convenience of description, the description may be first made with reference to a process plan view of FIG. 7 to FIG. 11 and a process cross-sectional view of FIGS. 12 to 16.

Referring to FIG. 7 and FIG. 12, a first electrode layer 110 having a predetermined area may be formed.

The first electrode layer 110 may be made of the same material as a material of the first active layer ACT1 or the second active layer ACT1 and may be disposed in the same layer as a layer of the first active layer ACT1 or the second active layer ACT1.

Accordingly, the first electrode layer 110 may be referred to as a test active layer.

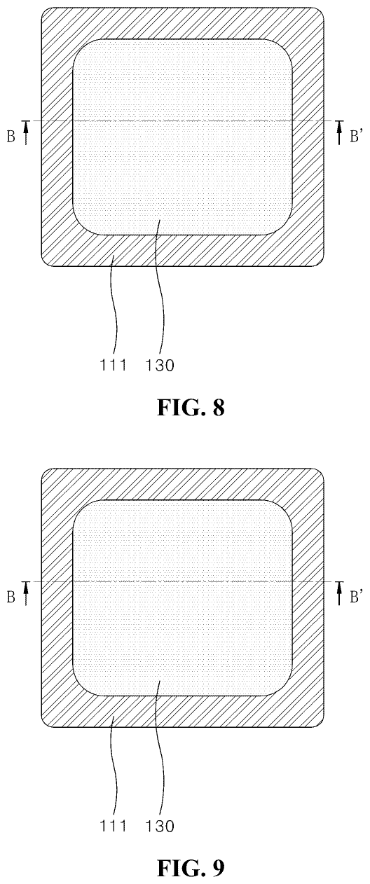

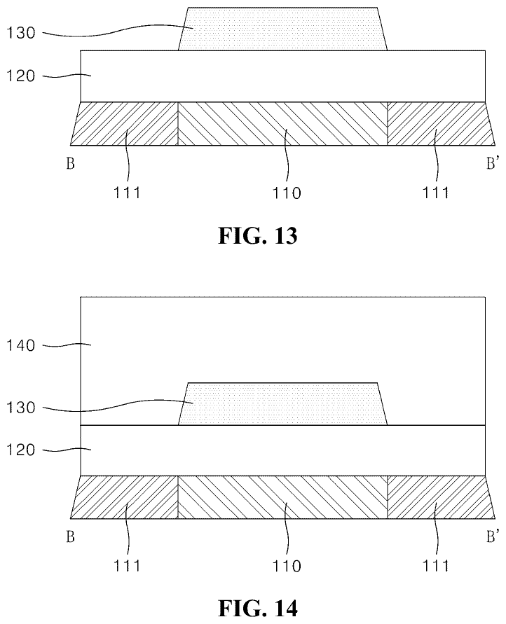

Referring to FIG. 8 and FIG. 13, a first insulating layer 120 may be formed on the first electrode layer 110.

The first insulating layer 120 may be made of the same material as a material of the first gate insulating layer GI1 or the second gate insulating layer GI2 and may be disposed in the same layer as a layer of the first gate insulating layer GI1 or the second gate insulating layer GI2.

A second electrode layer 130 may be formed on the first insulating layer 120.

The second electrode layer 130 may be positioned to overlap the first electrode layer 110 in the vertical direction so as not to cover an edge of the first electrode layer 110 so as to be exposed. Thus, edges of the first electrode layer 110 extend past edges of the second electrode layer 130 such that the second electrode layer 130 is non-overlapping with the edges of the first electrode layer 110.

Accordingly, the first electrode layer 110 may be formed to have a larger area than that of the second electrode layer 130. That is, an area of the first electrode layer 110 is greater than an area of the second electrode layer 130.

The second electrode layer 130 may be made of the same material as that of the first gate electrode layer GATE1 or the second gate electrode layer GATE2, and may be disposed in the same layer as a layer of the first gate electrode layer GATE1 or the second gate electrode layer GATE2.

The edge of the first electrode layer 110 not covered with the second electrode layer 130 is doped with impurity ions such as phosphorus (P) or boron (B) and thus may be a conductivized area. That is, the edge of the first electrode layer 110 that is non-overlapping with the second electrode layer 130 is doped with the impurity ions.

Accordingly, the first electrode layer 110 may include the conductivized area 111 that is non-overlapping with the second electrode layer 130 in the vertical direction.

An area other than the conductivized area 111 in the first electrode layer 110 may be a non-conductive area.

An area of the first insulating layer 120 corresponding to an area where the first electrode layer 110 and the second electrode layer 130 overlap each other except for the conductivized area 111 of the first electrode layer 110 formed in this way may be substantially may be an evaluation area of the first insulating layer 120.

Referring to FIG. 9 and FIG. 14, a second insulating layer 140 may be formed on the second electrode layer 130.

The second insulating layer 140 may be made of the same material as a material of one of the second interlayer insulating layer ILD2, the third interlayer insulating layer ILD3, the fourth interlayer insulating layer ILD4, and the fifth interlayer insulating layer ILD5 and may be disposed in the same layer as a layer of one of the second interlayer insulating layer ILD2, the third interlayer insulating layer ILD3, the fourth interlayer insulating layer ILD4, and the fifth interlayer insulating layer ILD5.

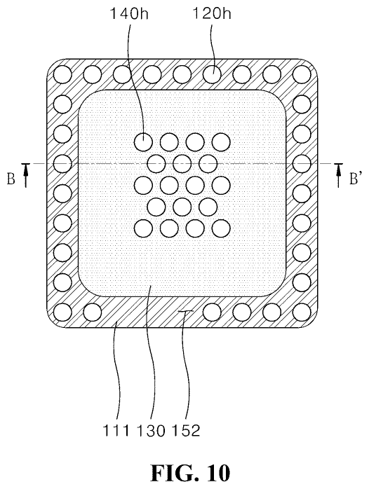

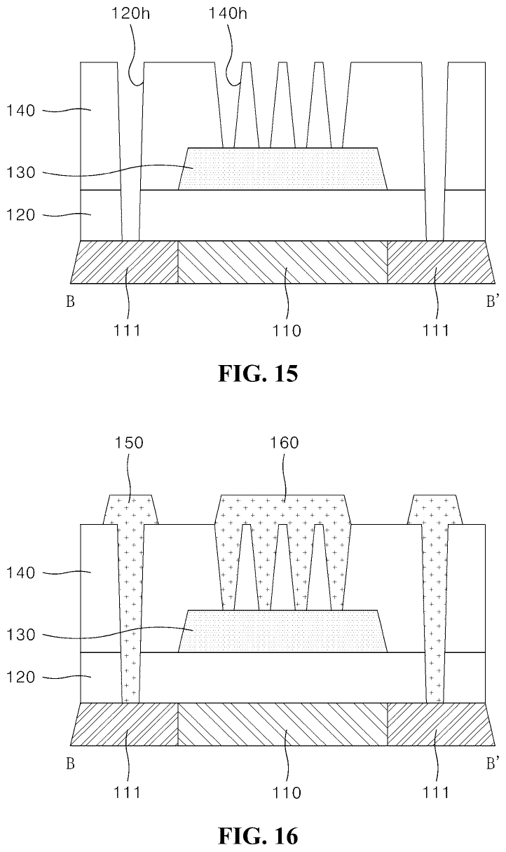

Referring to FIG. 10 and FIG. 15, a plurality of first contact holes 120h may be formed in the conductivized area 111 formed along an edge of the first electrode layer 110.

The first contact hole 120h may be formed to extend through the second insulating layer 140 and the first insulating layer 120.

The plurality of first contact holes 120h arranged along the conductivized area 111 may be positioned to be spaced apart from each other by a predetermined spacing. That is, the first contact holes 120h overlap the conductivized area 111.

The plurality of first contact holes 120h may be arranged as close to each other as possible. However, in a partial area, an opening 152 may be formed between adjacent first contact holes 120h such that a distance between the adjacent first contact holes 120h is relatively larger. That is, the first test wiring 150 overlaps a first portion of the conductivized area 111 and is non-overlapping with a second portion of the conductivized area 111. The second portion of the conductivized area 111 corresponds to the opening 152 in the first test wiring 150. The second test wiring 160 overlaps the second portion of the conductivized area 111.

The first contact hole 120h may not be formed in a portion of the conductivized area 111 corresponding to the opening 152 formed in this way.

A plurality of second contact holes 140h may be formed on the second electrode layer 130 so as to overlap the second electrode layer 130 in the vertical direction.

The second contact holes 140h may be formed in an area corresponding to the second electrode layer 130 so as to extend through the second insulating layer 140.

The plurality of second contact holes 140h may be arranged to be spaced apart from each other by a predetermined spacing. In one embodiment, the plurality of second contact holes 140h are arranged in a plurality of rows and a plurality of columns of second contact holes 140h.

The second contact holes 140h arranged in different columns or rows may be arranged in a staggered manner or a zigzag shape.

For example, the second contact hole 140h disposed in a second row may be located between two adjacent second contact holes 140h disposed in a first row and may be located between two adjacent second contact holes 140h disposed in the third row.

Additionally, the second contact hole 140h disposed in the third row may be located between two adjacent second contact holes 140h disposed in the second row, and may be located between two adjacent second contact holes 140h disposed in a fourth row.

As the second contact holes 140h arranged in different columns or rows are arranged in the staggered manner or the zigzag shape, many contact holes as possible may be formed within a certain area. Thus, a density of an area occupied with the contact hole may be increased.

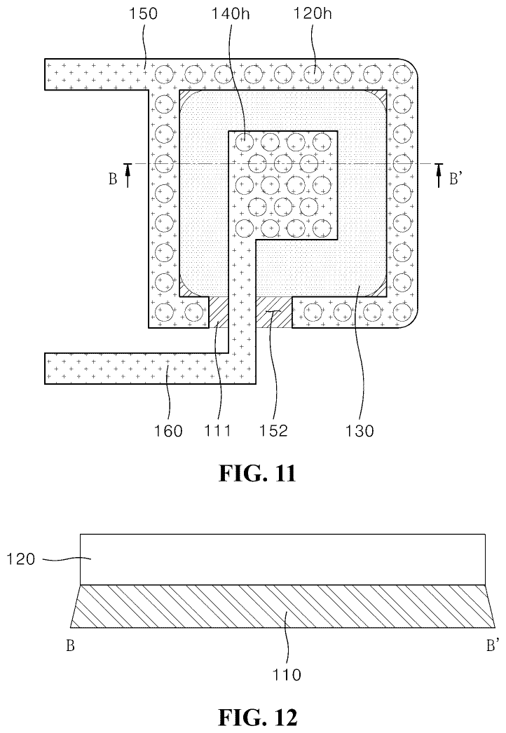

When the second contact holes 140h are arranged in the high density, the second contact holes 140h which serve as a path through which current passes may be arranged as evenly as possible, such that current may flow as evenly as possible throughout an entire area of the second electrode layer 130. Referring to FIG. 11 and FIG. 16, a first test wiring 150 electrically connected to the first electrode layer 110 via the first contact hole 120h, and a second test wiring 160 electrically connected to the second layer electrode 130 via the second contact hole 140h may be formed on the second insulating layer 140.

Each of the first test wiring 150 and the second test wiring 160 may be made of the same material as a material of the first source/drain electrode SD1 or the second source/drain electrode SD2 and may be disposed in the same layer as a layer of the first source/drain electrode SD1 or the second source/drain electrode SD2.

The first test wiring 150 may be disposed to cover the conductivized area 111 of the first electrode layer 110 where the first contact hole 120h is formed without covering the non-conductive area of the first electrode layer 110.

In this case, the first test wiring 150 may be formed to be continuous along the conductivized area 111, but may include an opening 152 in a partial area in which the first test wiring 150 is discontinuous.

The first test wiring 150 may be formed in a corresponding manner to the opening 152 formed between a pair of first contact holes 120h as described above.

The first test wiring 150 may be formed to extend in one side direction away from the first electrode layer 110 such that one end of the first test wiring 150 may be located outside the first electrode layer 110. That is, the end of the first test wiring 150 is non-overlapping with the first electrode layer 110.

The second test wiring 160 may be formed to cover the second electrode layer 130 on which the second contact holes 140h are formed.

The second test wiring 160 may be formed to extend in one direction away from the second electrode layer 130 and the first electrode layer 110 such that one end of the second test wiring 160 may be located outside the second electrode layer 130. That is, the end of the second test wing 160 is non-overlapping with the second electrode layer 130 and the first electrode layer 110.

In this case, the second test wiring 160 may extend through the opening 152 formed in the first test wiring 150 and extend away from the first electrode layer 110.

Accordingly, the second test wiring 160 formed in the same layer as a layer of the first test wiring 150 may extend through the opening 152 of the first test wiring 150 and extend outwardly of the first electrode layer 110.

One end of the first test wiring 150 may be electrically connected to the first test pad 151 and one end of the second test wiring 160 disposed outside the first electrode layer 110 may be electrically connected to the second test pad 161. As shown in FIG. 5, the end of the first testing wiring 150 and the end of the second test wiring 160 are non-overlapping with the first electrode layer 110 in a plan view. Furthermore, the end of the first test wiring 150 and the end of the second test wiring 160 are on a same plane. Thus, the end of the second testing wiring 160 lacks a step in the vertical direction thereby reducing a likelihood of tearing in the second electrode layer 130.

In the first test pattern 100 according to an embodiment of the present disclosure as described above, the first test wiring 150 and the second test wiring 160 may be connected to the first electrode layer 110 and the second electrode layer 130 constituting the first test pattern 100 via the plurality of contact holes, respectively. Thus, the current may be applied to the first electrode layer 110 and the second electrode layer 130 via the first test wiring 150 and the second test wiring 160, respectively. Thus, the current may be applied as uniformly as possible to an entire area of each of the first electrode layer 110 and the second electrode layer 130.

In addition, in the first test pattern 100 according to an embodiment of the present disclosure, the separate first test wiring 150 may be connected to the first electrode layer 110 constituting the first test pattern 100 via the plurality of first contact holes 120h. Thus, the current may be applied to the first electrode layer 110 via the first test wiring 150. The first electrode layer 110 is not required to extend directly to the first test pad 151 so as to be connected to the first test pad 151.

This may prevent the breakdown of the first electrode layer 110 from occurring before the breakdown of the insulating film due to an increase in the resistance near the bottleneck area of the first electrode layer 110 which has a narrow width and is not sufficiently conductivized when the first electrode layer 110 of the first test pattern 100 acts as the active layer.

In addition, in the first test pattern 100 according to an embodiment of the present disclosure, the separate second test wiring 160 may be connected to the second electrode layer 130 constituting the first test pattern 100 via the plurality of second contact holes 140h. Thus, the current may be applied to the second electrode layer 120 via the second test wiring 160. The second electrode layer 130 is not required to extend directly to the second test pad 161 so as to be connected to the second test pad 161.

Accordingly, a step in the vertical direction of the second electrode layer 130 that may occur in an outer boundary area of the first electrode layer 110 may not occur, thereby preventing breakdown of the second electrode layer 130 from occurring before the breakdown of the insulating film due to an increase in resistance near the bottleneck area having the narrow width of the second electrode layer 130.

In addition, in the first test pattern 100 according to an embodiment of the present disclosure, the first test wiring 150 and the second test wiring 160 may be connected to the first electrode layer 110 and the second electrode layer 130 constituting the first test pattern 100 via the plurality of contact holes, respectively. Thus, the current may be applied to the first electrode layer 110 and the second electrode layer 130 via the first test wiring 150 and the second test wiring 160, respectively. Thus, the current may be applied as uniformly as possible to an entire area of each of the first electrode layer 110 and the second electrode layer 130. There is no need to extend the first electrode layer 110 and the second electrode layer 130 outwardly such that the first electrode layer 110 and the second electrode layer 130 are directly connected to the first test pad 151 and the second test pad 161, respectively.

Accordingly, an overlapping area of the first electrode layer 110 and the second electrode layer 130 which may define the evaluation area of the insulating film to be measured may be defined more precisely.

That is, the evaluation area of the insulating film may be an area of a portion of the first insulating layer 120 that is disposed between and overlaps the first electrode layer 110 and the second electrode layer 130 except for the conductivized area 111.

In addition, in the first test pattern 100 according to an embodiment of the present disclosure, the first test wiring 150 and the second test wiring 160 may be connected to the first electrode layer 110 and the second electrode layer 130 constituting the first test pattern 100 via the plurality of contact holes, respectively. Thus, the current may be applied to the first electrode layer 110 and the second electrode layer 130 via the first test wiring 150 and the second test wiring 160, respectively. Thus, the defect characteristics inherent in the insulating film itself may be evaluated without being influenced as much as possible by the process influences due to the process. Thus, the consistency of the characteristics evaluation of the insulating film may be improved.

The first test pattern 100 as described above may be formed to have a generally square shape.

For example, each of the first electrode layer 110 and the second electrode layer 130 is formed to have generally a rectangular shape. Thus, the evaluation area of the first insulating layer 120 defined as the area of the first insulating layer 120 overlapping the first electrode layer 110 and the second electrode layer 130 may have generally a rectangular shape.

In this way, when the first test pattern 100 is formed to have a generally rectangular shape, there is an advantage that the evaluation area of the first insulating layer 120 may be more easily defined.

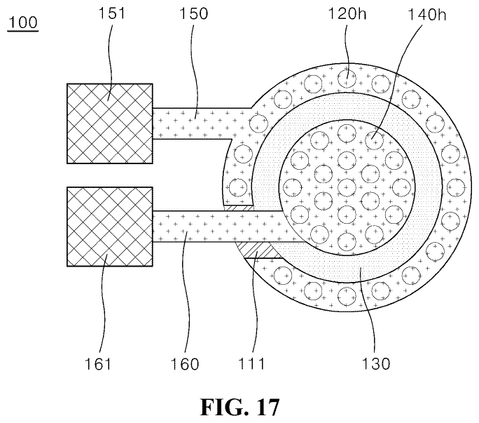

In one example, referring to FIG. 17, the first test pattern 100 according to another embodiment of the present disclosure may be formed to have a generally circular shape.

For example, each of the first electrode layer 110 and the second electrode layer 130 is formed to have generally a circular shape. Thus, the evaluation area of the first insulating layer 120 defined as the area of the first insulating layer 120 overlapping the first electrode layer 110 and the second electrode layer 130 may have generally a circular shape.

When the first test pattern 100 is formed to have a generally circular shape, this may be more advantageous in terms of current flow, compared to a case when the first test pattern 100 has the rectangular shape.

The shape of the first test pattern 100 is not limited to the rectangular and circular shapes as described above, and may be implemented to have various shapes.

The first test pattern 100 according to still another embodiment of the present disclosure may be formed to have contact holes of various sizes.

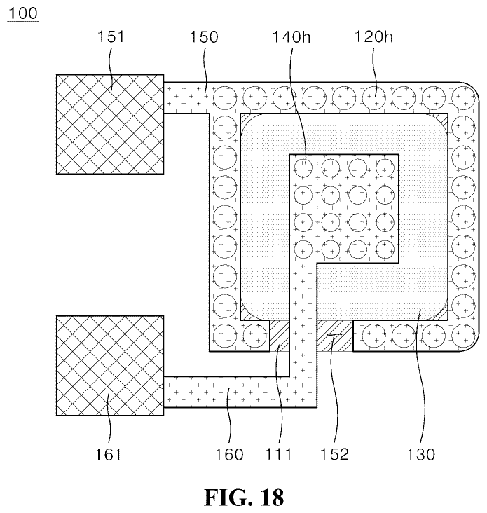

For example, referring to FIG. 18, the size of the first contact hole 120h may be formed to be larger. In one embodiment, the first contact hole 120h is larger than the second contact hole 140h.

However, the present disclosure is not limited thereto and the size of the first contact holes 120h may be smaller.

Additionally, the second contact holes 140h may be formed to be larger or smaller in size.

Additionally, the second contact holes 140h arranged in different columns or rows may be arranged to be aligned with each other such that centers of second contact holes 140h that are in the same row are aligned and centers of second contact holes 150h that are in the same column are aligned.

Even when the contact holes are modified to have various sizes, the first contact holes 120h and the second contact holes 140h may be uniformly arranged across an entire area of each of the first electrode layer 110 and the second electrode layer 130 such that the current as uniform as possible may be applied to the entire area of each of the first electrode layer 110 and the second electrode layer 130.

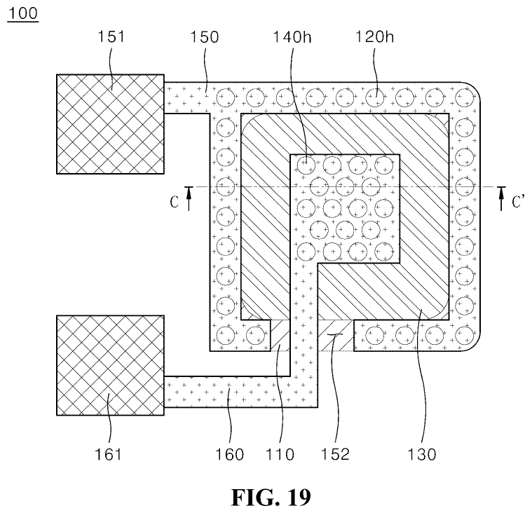

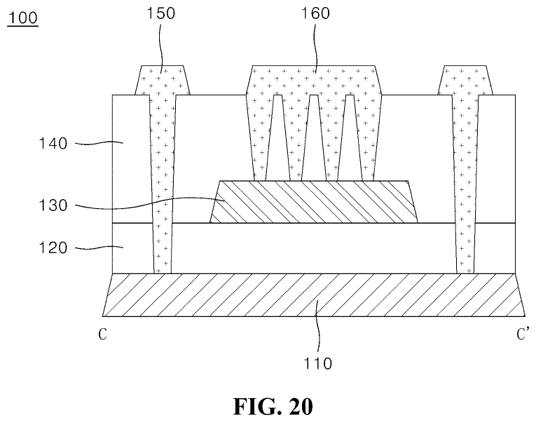

In one example, the first test pattern 100 according to still yet another embodiment of the present disclosure will be described with reference to FIG. 19 and FIG. 20. In this embodiment, the second electrode layer 130 may be the test active layer.

For example, the first electrode layer 110 as a lower layer may be made of the same material as a material of the light-blocking layer BSM or the first metal pattern layer TM1 and may be disposed in the same layer as a layer of the light-blocking layer BSM or the first metal pattern layer TM1.

The second electrode layer 130 may be made of the same material as a material of the first active layer ACT1 or the second active layer ACT1 and may be disposed in the same layer as a layer of the first active layer ACT1 or the second active layer ACT1.

The first insulating layer 120 may be made of the same material as a material of the third buffer layer BUF3 or the fourth buffer layer BUF4 and may be disposed in the same layer as a layer of the third buffer layer BUF3 or the fourth buffer layer BUF4.

The second electrode layer 130 formed to have an area smaller than that of the first electrode layer 110 may not be subjected to separate conductivization. An area of a portion of the first insulating layer 120 overlapping the first electrode layer 110 and the second electrode layer 130 may substantially be the evaluation area of the first insulating layer 120.

In this way, the second electrode layer 130 is the test active layer and the first electrode layer 110 is the metal layer. Thus, the film characteristics of other types of insulating films such as the buffer layers in addition to the gate insulating layer may be evaluated while maintaining a shape of a capacitor test pattern of the MOS structure.

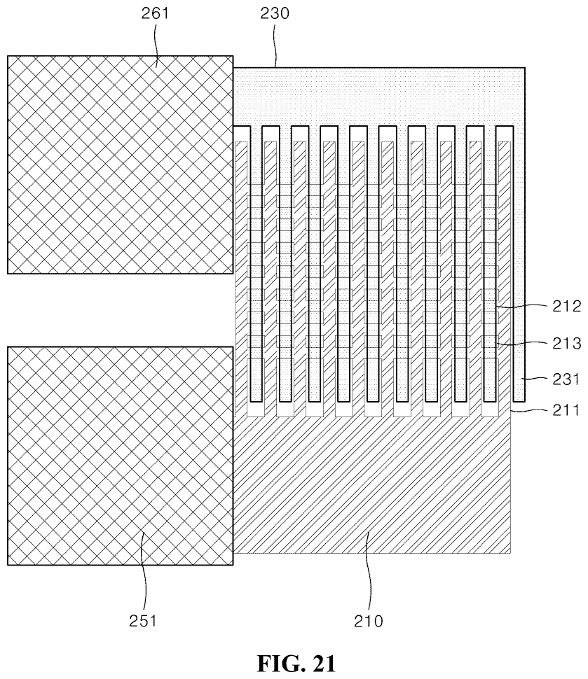

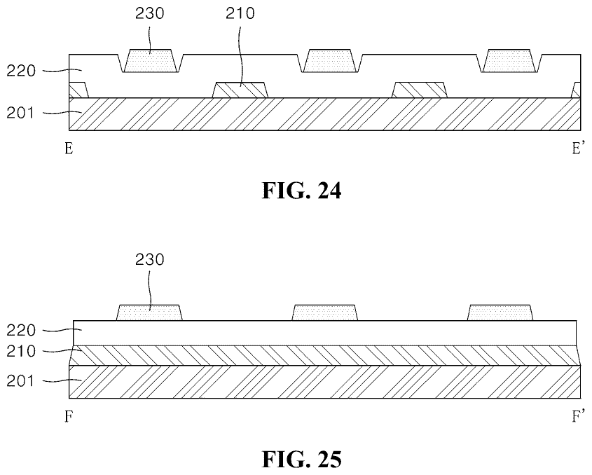

Hereinafter, referring to FIGS. 21 to 26, a second test pattern 200 according to an embodiment of the present disclosure will be described.

The second test pattern 200 may include a first electrode layer 210 including a grid pattern 211, a plurality of extensions 231 extending along one direction, and a second electrode layer 230 disposed to face the first electrode layer 210.

A first insulating layer 220 may be formed between the first electrode layer 210 and the second electrode layer 230.

The first electrode layer 210 may be made of the same material as a material of the first active layer ACT1 or the second active layer ACT1 and may be disposed in the same layer as a layer of the first active layer ACT1 or the second active layer ACT1.

Accordingly, the first electrode layer 210 may be referred to as a test active layer.

The first insulating layer 220 may be made of the same material as a material of the first gate insulating layer GI1 or the second gate insulating layer GI2 and may be disposed in the same layer as a layer of the first gate insulating layer GIL or the second gate insulating layer GI2.

The second electrode layer 230 may be made of the same material as a material of the first gate electrode layer GATE1 or the second gate electrode layer GATE2 and may be disposed in the same layer as a layer of the first gate electrode layer GATE1 or the second gate electrode layer GATE2.

However, embodiments of the present disclosure are not limited thereto. In the second test pattern 200 according to another embodiment of the present disclosure, the first electrode layer 210 may be made of the same material as a material of the light-blocking layer BSM or the first metal pattern layer TM1 and may be disposed in the same layer as a layer of the light-blocking layer BSM or the first metal pattern layer TM1.

In this case, the second electrode layer 230 may be made of the same material as a material of the first active layer ACT1 or the second active layer ACT1, and may be disposed in the same layer as a layer of the first active layer ACT1 or the second active layer ACT1. The first insulating layer 220 may be made of the same material as a material of the third buffer layer BUF3 or the fourth buffer layer BUF4 and may be disposed in the same layer as a layer of the third buffer layer BUF3 or the fourth buffer layer BUF4.

The grid pattern 211 may be formed to include a plurality of hollow spaces 213 and a connection portion 212 that defines the plurality of hollow spaces 213. In one embodiment, the hollow spaces 213 are openings in the first electrode layer 210 and the connection portion 212 is between the openings.

For example, the grid pattern 211 may be arranged in a matrix form in which the plurality of hollow spaces 213 are spaced apart from each other while the connection portion 212 is disposed therebetween.

The first electrode layer 210 may extend such that one side thereof is electrically connected to a first test pad 251.

The plurality of extensions 231 of the second electrode layer 230 may be positioned to overlap the grid pattern 211 of the first electrode layer 210 in the vertical direction.

For example, the plurality of extensions 231 of the second electrode layer 230 may be positioned to vertically overlap the plurality of hollow spaces 213 arranged along one direction. An extension 231 may overlap at least one hollow space 213.

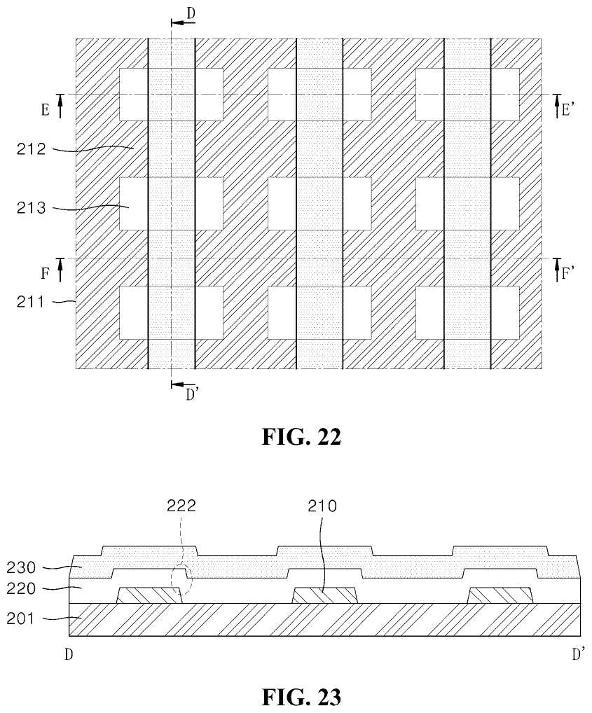

Referring to FIGS. 22 to 25, the first electrode layer 210, the first insulating layer 220, and the second electrode layer 230 may be sequentially stacked on a buffer layer 201.

In this case, the hollow spaces 213 of the first electrode layer 210 arranged in the same direction in which the extension 231 of the second electrode layer 230 extends may be positioned to vertically overlap the extension 231.

Accordingly, referring to FIG. 23, the hollow spaces 213 and the connection portions 212 of the first electrode layer 210 may be arranged to alternately overlap with the extensions 231 of the second electrode layer 230 extending in one direction. For example, an extension from the plurality of extensions 231 includes a first portion that overlaps a first opening (e.g., a first hollow space), a second portion that overlaps a second opening (e.g., a second hollow space), and a third portion that overlaps a portion of the connection portion 212 that is between the first opening and the second opening in a plan view of the test pattern.

In this case, the extension 231 may include a plurality of step areas 222 disposed at a boundary between the hollow space 213 and the connection portion 212.

That is, the extension 231 may be formed so that the plurality of step areas 222 are spaced apart from each other by a predetermined spacing in a corresponding manner to steps of the first insulating layer 220 that occurs at the boundaries between the hollow spaces 213 and the connection portion 212.

The second electrode layer 230 may extend such that one side thereof is electrically connected to a second test pad 261.

In the second test pattern 200 according to an embodiment of the present disclosure as described as above, the first electrode layer 210 and the second electrode layer 230 constituting the second test pattern 200 may include the grid pattern 211 and the extensions 231, respectively, which are positioned to vertically overlap each other.

Accordingly, a large number of step areas 222 may be respectively formed in areas where the grid pattern 211 of the matrix shape and the extensions 231 overlap each other.

Due to the large number of step areas 222 formed in this way, the number of evaluation samplings that may be used to evaluate the step coverage of the insulating film increases, such that the characteristics such as the step coverage of the insulating film affected by the process influence due to the process as the extrinsic factor may be evaluated more accurately and precisely.

In addition, in the second test pattern 200 according to an embodiment of the present disclosure, the first electrode layer 210 and the second electrode layer 230 constituting the second test pattern 200 may include the grid pattern 211 and the extensions 231, respectively, which are positioned to vertically overlap each other.

Accordingly, unlike a test pattern that breaks down all at once, the breakdown may occur in the test pattern several times step-by-step. Thus, the characteristics of the insulating film under the process influence may be evaluated more accurately and precisely.

The number of cross patterns formed when the extensions 231 of the second electrode layer 230 intersect the grid pattern 211 of the first electrode layer 210 is not particularly limited.

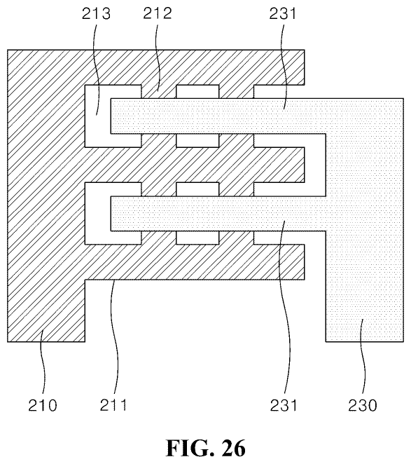

For example, referring to FIG. 26, the number of the cross patterns formed when the extensions 231 of the second electrode layer 230 intersect the grid pattern 211 of the first electrode layer 210 may be 2×2. However, embodiments of the present disclosure are not limited thereto. The number of the cross patterns may be 3×3 or 10×10, etc.

In evaluating the breakdown characteristics of the insulating film under current application using the second test pattern 200, a current path may vary per a unit subject to the evaluation.

Accordingly, the second test pattern 200 according to an embodiment of the present disclosure is modified to have a diverse number of cross patterns, so that the uniform current path may be formed per a unit subject to evaluation.

A test pattern and a display device according to some aspects and embodiments of the present disclosure as described above may be described as follows.

A first aspect of the present disclosure provides a test pattern comprising: a first electrode layer; a first insulating layer disposed on the first electrode layer; a second electrode layer disposed on the first insulating layer so as not to cover an edge of the first electrode layer so as to be exposed; a second insulating layer disposed on the second electrode layer; a first test wiring disposed on the second insulating layer, wherein the first test wiring is connected to the first electrode layer via a plurality of first contact holes extending through the first insulating layer and the second insulating layer; and a second test wiring disposed on the second insulating layer, wherein the second test wiring is connected to the second electrode layer via a plurality of second contact holes extending through the second insulating layer.

In accordance with some embodiments of the test pattern of the first aspect, the test pattern further comprises a first test pad and a second test pad respectively connected to the first test wiring and the second test wiring, wherein one end of the first test wiring connected to the first test pad and one end of the second test wiring connected to the second test pad are located outside the first electrode layer in a plan view of the test pattern.

In accordance with some embodiments of the test pattern of the first aspect, the first electrode layer is a test active layer, wherein the first electrode layer includes a conductivized area formed along an edge thereof, wherein the plurality of first contact holes are arranged along the conductivized area.

In accordance with some embodiments of the test pattern of the first aspect, the first test wiring extending along the conductivized area includes an opening through which the second test wiring extending outwardly of the first electrode layer extends.

In accordance with some embodiments of the test pattern of the first aspect, the first test wiring and the second test wiring are made of the same material and are disposed in the same layer.

In accordance with some embodiments of the test pattern of the first aspect, the plurality of second contact holes are positioned to overlap the second electrode layer in a vertical direction.

In accordance with some embodiments of the test pattern of the first aspect, the second electrode layer is a test active layer, wherein the plurality of first contact holes are arranged along an edge of the first electrode layer.

A second aspect of the present disclosure provides a test pattern comprising: a first electrode layer including a grid pattern; a first insulating layer disposed on the first electrode layer; and a second electrode layer disposed on the first insulating layer, wherein the second electrode layer includes a plurality of extensions extending along one direction, wherein the extensions are positioned to overlap the grid pattern in a vertical direction.

In accordance with some embodiments of the test pattern of the second aspect, the grid pattern includes: a plurality of hollow spaces; and a connection portion defining the plurality of hollow spaces, wherein each of the extensions is positioned to overlap the plurality of hollow spaces arranged along the one direction.

In accordance with some embodiments of the test pattern of the second aspect, the hollow spaces and the connection portion are arranged to alternately overlap with the extensions extending in the one direction.

In accordance with some embodiments of the test pattern of the second aspect, the extension includes a plurality of step areas respectively disposed at borders between the hollow spaces and the connection portion.

In accordance with some embodiments of the test pattern of the second aspect, the test pattern further comprises: a first test pad electrically connected to the first electrode layer; and a second test pad electrically connected to the second electrode layer.

A third aspect of the present disclosure provides a display device comprising: a substrate including a display area and a non-display area; and at least one test pattern disposed on the non-display area of the substrate, wherein the test pattern includes: a first electrode layer; a first insulating layer disposed on the first electrode layer; a second electrode layer disposed on the first insulating layer so as not to cover an edge of the first electrode layer so as to be exposed; a second insulating layer disposed on the second electrode layer; a first test wiring disposed on the second insulating layer, wherein the first test wiring is connected to the first electrode layer via a plurality of first contact holes extending through the first insulating layer and the second insulating layer; and a second test wiring disposed on the second insulating layer, wherein the second test wiring is connected to the second electrode layer via a plurality of second contact holes extending through the second insulating layer.

In accordance with some embodiments of the display device of the third aspect, the display device further comprises: a light-blocking layer disposed on the substrate; a buffer layer disposed on the light-blocking layer; an active layer disposed on the buffer layer; a gate insulating layer disposed on the active layer; and a gate electrode layer disposed on the gate insulating layer, wherein the first insulating layer is the buffer layer or the gate insulating layer.

In accordance with some embodiments of the display device of the third aspect, when the first insulating layer is the buffer layer, the first electrode layer and the light-blocking layer are disposed in the same layer, and the second electrode layer and the active layer are disposed in the same layer.

In accordance with some embodiments of the display device of the third aspect, when the first insulating layer is the gate insulating layer, the first electrode layer and the active layer are disposed in the same layer, and the second electrode layer and the gate electrode layer are disposed in the same layer.

A fourth aspect of the present disclosure provides a display device comprising: a substrate including a display area and a non-display area; and at least one test pattern disposed on the non-display area of the substrate, wherein the test pattern includes: a first electrode layer including a grid pattern; a first insulating layer disposed on the first electrode layer; and a second electrode layer disposed on the first insulating layer, wherein the second electrode layer includes a plurality of extensions extending along one direction, wherein the extensions are positioned to overlap the grid pattern in a vertical direction.

In accordance with some embodiments of the display device of the fourth aspect, the display device further comprises: a light-blocking layer disposed on the substrate; a buffer layer disposed on the light-blocking layer; an active layer disposed on the buffer layer; a gate insulating layer disposed on the active layer; and a gate electrode layer disposed on the gate insulating layer, wherein the first insulating layer is the buffer layer or the gate insulating layer.

In accordance with some embodiments of the display device of the fourth aspect, when the first insulating layer is the buffer layer, the first electrode layer and the light-blocking layer are disposed in the same layer, and the second electrode layer and the active layer are disposed in the same layer.

In accordance with some embodiments of the display device of the fourth aspect, when the first insulating layer is the gate insulating layer, the first electrode layer and the active layer are disposed in the same layer, and the second electrode layer and the gate electrode layer are disposed in the same layer.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A test pattern comprising:
a first electrode layer;
a first insulating layer on the first electrode layer;
a second electrode layer on the first insulating layer, the second electrode layer non-overlapping with an edge of the first electrode layer;
a second insulating layer on the second electrode layer;
a first test wiring on the second insulating layer, the first test wiring connected to the first electrode layer via a plurality of first contact holes that extend through the first insulating layer and the second insulating layer; and
a second test wiring on the second insulating layer, the second test wiring connected to the second electrode layer via a plurality of second contact holes that extend through the second insulating layer.

2. The test pattern of claim 1, wherein the test pattern further comprises:
a first test pad that is connected to an end of the first test wiring; and
a second test pad that is connected to an end of the second test wiring,
wherein the end of the first test wiring and the end of the second test wiring are non-overlapping with the first electrode layer in a plan view of the test pattern.

3. The test pattern of claim 1, wherein the first electrode layer is a test active layer and the first electrode layer includes a conductivized area along the edge of the first electrode layer, the plurality of first contact holes overlapping the conductivized area.

4. The test pattern of claim 3, wherein the first test wiring overlaps a first portion of the conductivized area and is non-overlapping with a second portion of the conductivized area, and the second test wiring overlaps the second portion of the conductivized area.

5. The test pattern of claim 4, wherein the first test wiring and the second test wiring are made of a same material and are on a same layer.

6. The test pattern of claim 1, wherein the plurality of second contact holes overlap the second electrode layer.

7. The test pattern of claim 1, wherein the second electrode layer is a test active layer and the plurality of first contact holes are arranged along the edge of the first electrode layer.

8. A test pattern comprising:
a first electrode layer including a grid pattern of a plurality of openings in the first electrode layer;
a first insulating layer on the first electrode layer; and
a second electrode layer on the first insulating layer, the second electrode layer including a plurality of extensions that overlap the grid pattern of the plurality of openings.

9. The test pattern of claim 8, wherein the grid pattern further includes:
a connection portion between the plurality of openings,
wherein each of the plurality of extensions overlaps at least one of the plurality of openings and the connection portion.

10. The test pattern of claim 9, wherein an extension from the plurality of extensions includes a first portion that overlaps a first opening from the plurality of openings, a second portion that overlaps a second opening from the plurality of openings, and a third portion that overlaps a portion of the connection portion that is between the first opening and the second opening in a plan view of the test pattern.

11. The test pattern of claim 9, wherein each of the plurality of extensions includes a plurality of step areas at borders between the plurality of openings and the connection portion.

12. The test pattern of claim 11, wherein the test pattern further comprises:
a first test pad that is electrically connected to the first electrode layer; and
a second test pad that is electrically connected to the second electrode layer.

13. A display device comprising:
a substrate including a display area and a non-display area; and
at least one test pattern on the non-display area of the substrate, the at least one test pattern including:
a first electrode layer;
a first insulating layer on the first electrode layer;
a second electrode layer on the first insulating layer, the second electrode layer non-overlapping with an edge of the first electrode layer;
a second insulating layer on the second electrode layer;
a first test wiring on the second insulating layer, the first test wiring connected to the first electrode layer via a plurality of first contact holes that extend through the first insulating layer and the second insulating layer; and
a second test wiring on the second insulating layer, the second test wiring connected to the second electrode layer via a plurality of second contact holes that extend through the second insulating layer.

14. The display device of claim 13, wherein the display device further comprises:
a light-blocking layer in the display area of the substrate;
a buffer layer on the light-blocking layer;
an active layer on the buffer layer in the display area;
a gate insulating layer on the active layer; and
a gate electrode layer on the gate insulating layer in the display area,
wherein the first insulating layer is a portion of the buffer layer that is in the non-display area or the first insulating layer is a portion of the gate insulating layer that is in the non-display area.

15. The display device of claim 14, wherein the first electrode layer and the light-blocking layer are in a same layer and the second electrode layer and the active layer are in a same layer when the first insulating layer is the portion of the buffer layer that is in the non-display area.

16. The display device of claim 14, wherein the first electrode layer and the active layer are in a same layer and the second electrode layer and the gate electrode layer are in a same layer when the first insulating layer is the portion of the gate insulating layer that is in the non-display area.

17. A display device comprising:
a substrate including a display area and a non-display area; and
at least one test pattern on the non-display area of the substrate, the at least one test pattern including:
a first electrode layer including a grid pattern of a plurality of openings in the first electrode layer;
a first insulating layer on the first electrode layer; and
a second electrode layer on the first insulating layer, the second electrode layer including a plurality of extensions that overlap the grid pattern of the plurality of openings.

18. The display device of claim 17, wherein the display device further comprises:
a light-blocking layer in the display area of the substrate;
a buffer layer on the light-blocking layer;
an active layer on the buffer layer in the display area;
a gate insulating layer on the active layer; and
a gate electrode layer on the gate insulating layer in the display area,
wherein the first insulating layer is a portion of the buffer layer that is in the non-display area or the first insulating layer is a portion of the gate insulating layer that is in the non-display area.

19. The display device of claim 18, wherein the first electrode layer and the light-blocking layer are in a same layer and the second electrode layer and the active layer are in a same layer when the first insulating layer is the portion of the buffer layer that is in the non-display area.

20. The display device of claim 18, wherein the first electrode layer and the active layer are in a same layer and the second electrode layer and the gate electrode layer are in a same layer when the first insulating layer is the portion of the gate insulating layer that is in the non-display area.

21. A test pattern comprising:
a first electrode layer;
a first insulating layer on the first electrode layer;
a second electrode layer on the first insulating layer, the second electrode layer non-overlapping with an edge of the first electrode layer;
a second insulating layer on the second electrode layer;
a first test wiring on the second insulating layer, the first test wiring connected to the first electrode layer; and
a second test wiring on the second insulating layer, the second test wiring connected to the second electrode layer,
wherein an end of the first test wiring and an end of the second test wiring are on a same plane.

22. The test pattern of claim 21, further comprising:
a first test pad that is connected to the end of the first test wiring; and
a second test pad that is connected to the end of the second test wiring.

23. The test pattern of claim 22, wherein the end of the first test wiring and the end of the second test wiring are non-overlapping with the first electrode layer in a plan view of the test pattern.

24. The test pattern of claim 21, further comprising:
a plurality of first contact holes that extend through the first insulating layer and the second insulating layer; and
a plurality of second contact holes that extend through the second insulating layer,
wherein the first test wiring is connected to the first electrode layer via the plurality of first contact holes and the second test wiring is connected to the second electrode layer via the plurality of second contact holes.
